(19) United States
(12) Patent Application Publication
(10) Pub. No.: US 2017/0332479 A1
(43) Pub. Date: Nov. 16, 2017

(54) MULTI-FLEX PRINTED CIRCUIT BOARD FOR WEARABLE SYSTEM

(71) Applicant: Titanium Falcon Inc., Sunnyvale, CA (US)

(72) Inventor: Fu LUO-LARSON, Milpitas, CA (US)

(21) Appl. No.: 15/499,623

(22) Filed: Apr. 27, 2017

Related U.S. Application Data
(60) Provisional application No. 62/335,079, filed on May 12, 2016.

(51) Int. Cl. H05K 1/02; H05K 3/02; H05K 1/18; H05K 1/03; H05K 1/14; H05K 1/09; H05K 3/34

(52) U.S. Cl. CPC H05K 1/028; H05K 3/3415; H05K 3/025; H05K 1/189; H05K 1/036; H05K 1/144; H05K 1/09; H05K 1/181

(57) ABSTRACT

Disclosed is a printed circuit board (PCB) design for a multi-flex PCB system aimed at wearable devices that is capable of meeting requirements such as ultra-thin thickness profile of the board (thereby allowing 360 degree of bendability) and less manufacturing cost, as desired by consumer electronics, such as wearable motion controlled mobile gaming devices. The PCB design suggests two thickness levels for the multi-flex PCB system. The thicker parts are four-layer sections with 20 mils thickness and thinner parts are two-layer sections with 7-8 mils thickness. The ground and supply planes are only solid on the four-layer sections. Since the two-layer segments including signal paths are completely bendable, the entire rectangular board can bend as a cycle. This two thickness-level structure can be easily modified to three thickness-level structure with the third three-layer sections with 12-13 mils thickness. The three thickness-level structure is to accommodate more complicated electronics circuit design.

### FIELD OF THE INVENTION

This invention generally relates to printed circuit boards and more particularly to multi-flex printed circuit board systems for use in electronic wearable devices.

### BACKGROUND

Nowadays, electronic devices are involved in almost every human endeavor. Over time, a size of the electronic devices has reduced with simultaneous increase in the capability of these electronic devices. For example, a physical size of a mobile phone has drastically reduced over the years and at the same time the mobile phone, in addition to enabling a user to make and receive phone calls or send and receive messages, can now be used to click pictures, browse web, send and receive emails, play games etc.

One recent development in these attempts to make electronic devices, smaller, better and user-friendlier, is the advent of consumer wearable devices. Wearable devices include a range of products that are capable of being worn on a user's body for an extended period of time and are configured to significantly enhance a user experience as a result of the product's functions. Typically, the wearable devices contain advanced sensor circuitry and wireless connectivity, and they rely on smartphone application ecosystem to process the information. Nowadays, smartphone applications for wearable devices include software applications related to fitness, healthcare, automobile accessibility, outdoor activities, home infrastructure and even gaming.

In the case of gaming, options for wearable motion controlled gaming devices are being explored to solve many of the problems currently plaguing the gaming industry. For example, in order to play motion-controlled games, typically, a user must purchase expensive hardware and related software, such as for example suitable displays, gaming consoles (for example, Wii or Xbox and Kinect), so on and so forth. Further, a large physical space is required to support this type of gaming. Furthermore, since the touch screen has small space for a virtual gamepad and a users' finger blocks some part of the gaming display area, the limited space and no tactile impression makes mobile gaming difficult to play. Wearable motion controlled mobile gaming devices are expected to improve the mobile gaming experience by offering a three-dimension touch less space instead of a two-dimension playfield touch screen.

As wearable motion controlled mobile gaming devices fall in the category of consumer electronic devices, a stylish and ergonomic design is required. However, developing wearable mobile gaming devices with stylish and ergonomic design and at the same time maximizing a user experience is difficult. For example, configuring wearable mobile gaming devices in round or circular shapes to configure an armband, a bracelet or a ring, while designing a printed circuit board (PCB) to fit in the various hardware components poses a significant challenge. A manufacturing cost of the PCB also has to be controlled to ensure the retail product is in a fairly affordable range.

### OBJECT OF INVENTION

The principal object of the embodiments herein is to provide a multi-flex PCB system for wearable devices that is ultra-thin and completely bendable.

### SUMMARY

The above-mentioned needs are met by a multi-flex printed circuit board for wearable systems.

A multi-flex printed circuit board for wearable systems includes a plurality of sections made up of flexible composites and a conductive material (such as copper) that allows complete bendability of the multi-flex board. Each section is configured with a desired combination of layers; one or more components soldered on top and/or bottom copper layer. The multi-flex board is configured to enable component assembly load on one or more thicker layer sections and routing capability to one or more thinner layer sections. The middle layers of the thicker layer section extend out to form the thinner layer section.

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF THE VIEWS OF DRAWINGS

In the accompanying figures, similar reference numerals may refer to identical or functionally similar elements. These reference numerals are used in the detailed description to illustrate various embodiments and to explain various aspects and advantages of the present disclosure.

FIG. 1A shows a simplified representation of a perspective view of a multi-flex board, in accordance with an example scenario;

FIG. 1B shows a cross sectional view of the multi-flex board of FIG. 1A, in accordance with an example scenario;

FIG. 2 shows a simplified representation of the multi-flex board of FIG. 1B including multiple component assembly areas, in accordance with an example scenario;

FIG. 3 shows a stack-up view of the multi-flex board of FIG. 1B in accordance with an example scenario;

FIG. 4 shows a simplified top-view representation of the multi-flex board for illustrating power and ground planes, in accordance with an example scenario;

FIG. 5 shows an example a printed circuit board (PCB) design of a multi-flex PCB, in accordance with an embodiment of the present invention;

FIG. 6 shows a perspective side view of a multi-flex board structure, in accordance with an example embodiment of the present invention;

FIG. 7 shows a simplified representation of a top view of a portion of the multi-flex board structure of FIG. 6 for illustrating ground planes, ground traces, power planes, power traces and signal path zone placements, in accordance with an example embodiment of the present invention;

FIG. 8 shows a stack-up view of the multi-flex PCB of FIG. 5, in accordance with an example embodiment of the present invention;

FIG. 9 shows a stack up view of a PCB design of ‘4-3-2 layers’ combination for a multi-flex board, in accordance with an embodiment of the present invention;

FIG. 10 shows an example electronic system for use in a motion controlled gaming device, in accordance with an embodiment of the present invention;

FIG. 11 shows an example representation of a motion controlled gaming device implemented as a ring of a user, in accordance with an example scenario; and

FIG. 12 depicts an example representation of a multi-flex PCB system disposed within an outer shell of a circular-shaped wearable motion controlled gaming device, in accordance with an embodiment of the present invention.

### DETAILED DESCRIPTION OF THE EMBODIMENTS

The above-mentioned needs are met by multi-flex printed circuit board for wearable systems. The following detailed description is intended to provide example implementations to one of ordinary skill in the art, and is not intended to limit the invention to the explicit disclosure, as one or ordinary skill in the art will understand that variations can be substituted that are within the scope of the invention as described.

The best and other modes for carrying out the present invention are presented in terms of the embodiments, herein depicted in FIGS. 5 to 12. The embodiments are described herein for illustrative purposes and are subject to many variations. It is understood that various omissions and substitutions of equivalents are contemplated as circumstances may suggest or render expedient, but are intended to cover the application or implementation without departing from the spirit or scope of the present invention. Further, it is to be understood that the phraseology and terminology employed herein are for the purpose of the description and should not be regarded as limiting. Any heading utilized within this description is for convenience only and has no legal or limiting effect. The terms “a” and “an” herein do not denote a limitation of quantity, but rather denote the presence of at least one of the referenced item.

It is noted that this invention relates to printed circuit board (PCB) systems for use in electronic devices, which include complex electronic components and require the internal PCBs to be completely bendable with all components on. It is understood that designing a PCB with a high flexibility requirement, especially for consumer electronic devices, poses significant challenges. For example, a PCB for a circular shaped wearable motion controlled mobile gaming device requires almost 360-degree flexibility. To being able to bend, the PCB has to include flexible parts. According to the amount of times that a PCB can be bent, two classification standards namely a semi-static standard and a dynamic standard are generally defined. For adhering to a semi-static standard, a PCB should be capable of flexing up to 20 times. For adhering to a dynamic standard, a PCB should be capable of being regularly twisted and flexed. As the PCB is not supposed to be twisted or flexed any more times once the PCB is assembled into the outer shell of the consumer electronic device such as a wearable gaming device, the PCB design should conform to a semi static standard.

In addition to the flexibility requirement, product reliability level and pricing also need to be considered. It is noted that three manufacturing classes are generally defined in terms of the product reliability level and the pricing. Class I relates to general electronic products where the major focus is on functionality. Class II relates to dedicated service electronics products where a higher performance and longer lifetime is demanded. This is a common class for consumer electronics such as gaming consoles. Class III relates to high reliability electronic products. For this class, the boards and the components' lifetime have to be assured and the highest reliability is required. Normally, applications related to military use or medical treatment need class III standard for the PCBs. Class III PCBs are most expensive ones among the three classes of PCBs on account of the special materials used and manufacturing process involved in their generation. As a result, PCB design for applications of consumer electronic devices, such as wearable gaming devices, may be chosen in a manner such that the design conforms to semi-static standard and dedicated to service electronic products in class II.

Typically, for designing a PCB with a high flexibility requirement for a consumer electronic device, such as a wearable motion controlled mobile gaming device, ‘flex PCB’ is preferred over other types of flexible PCBs, such as ‘rigid-flex PCB’ and ‘semi-flex PCBs’, as flex PCB provides a satisfactory balance between price and flexibility desired for consumer electronic devices. It is noted that materials normally used for designing a rigid-flex PCB include a combination of polyimide and flame retardant 4 (FR4). Since two materials (such as FR-4 and polyimide) are normally involved in manufacturing the rigid flex PCB, the manufacturing process is harder than flex PCB (which primarily uses only polyimide as a laminate) and thereby, the manufacturing cost is higher. Moreover, compared with the rigid-flex PCB, a flex PCB can be utilized in much more complex geometries and with greater spatial freedom. The flex PCB can also be built up as a single layer or a multilayer flex also called multi-flex board depending on electronics' system complexity.

A semi-flex PCB can be considered to be ultra-thin rigid-flex PCB. The semi-flex PCB normally uses FR4 thin laminate. The ultra-thin feature of the semi-flex PCB renders certain flexibility and generally speaking, FR4 costs less than the polyimide for manufacturing flex boards. However, according to different fabrication houses' capabilities, the semi-flex PCB can only be bent few times with a very limited bending radius, which may not serve the purpose for devices such as wearable devices, which are to be designed in the shape of a band, bracelet, pendant, charms, ring, earring, brooches, etc. In comparison with other types of flexible PCBs, the flex PCB has relatively good temperature and humidity tolerance with lower cost. Hence, it is the optimal type of PCBs in consumer electronic devices with high flexibility requirement, such as wearable gaming devices.

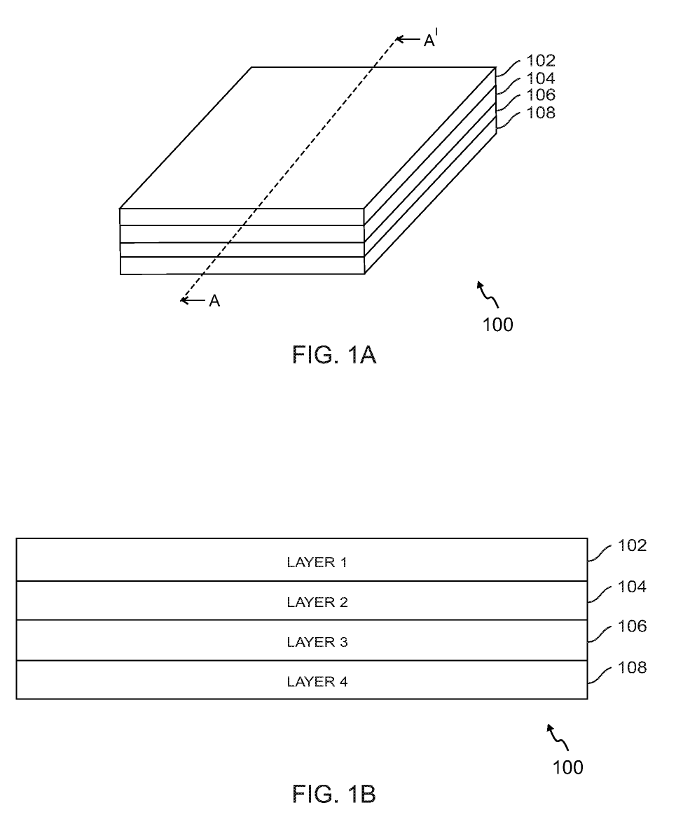

In addition to selecting an appropriate type of PCB (for example, a flex PCB with a design conforming to a semi-static standard and dedicated to service electronic products in class II), determination of how to create a stack-up of the layers that would compose a multi-flex board that is completely bendable is also critical. Flex PCB normally gives a degree of bendability, however, being able to bend 360 degree relies on the consideration of a number of layers included in the stack. It is understood that having more layers increases a flexibility of routing, however, a thickness of the multi-flex board increases. Thus, in terms of the demands of the bendability and complexity of consumer electronic devices, such as wearable motion controlled mobile gaming systems, a maximum four-layer multi-flex PCB is the best compromise. Further, choosing a right architecture of the four-layer board is also important. A multi-flex board can be implemented to include a constant number of layers as exemplarily depicted in FIGS. 1A and 1B.

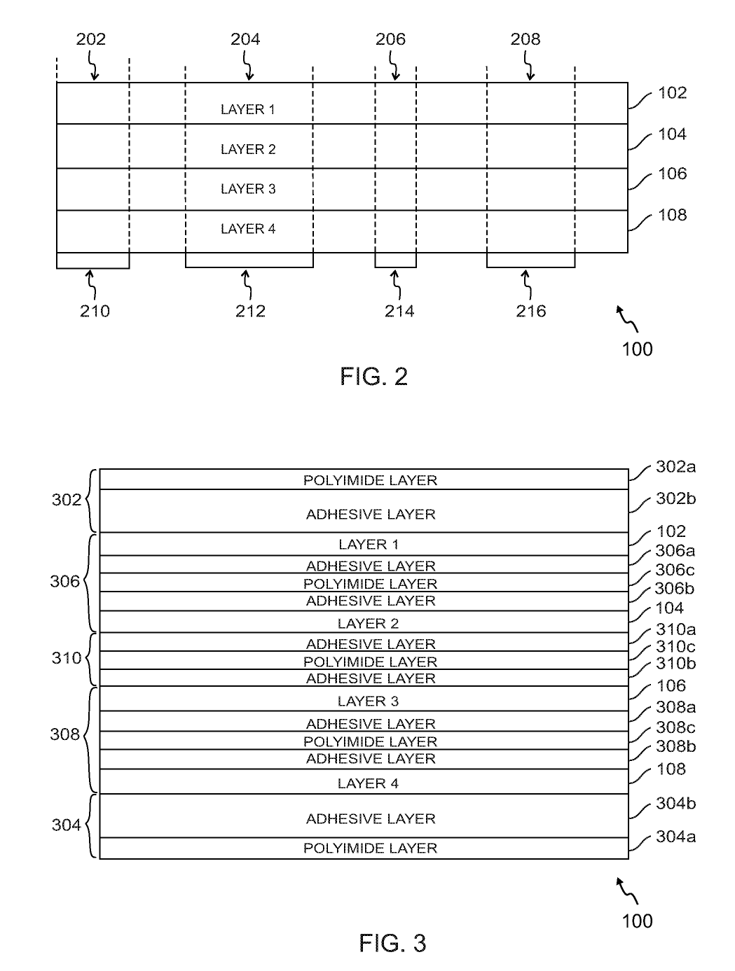

FIG. 1A shows a simplified representation of a perspective view of a multi-flex board 100 and FIG. 1B shows a cross sectional view of the multi-flex board 100 of FIG. 1A, in accordance with an example scenario. FIG. 1A depicts the multi-flex board 100 including four layers 102, 104, 106 and 108. A cross-sectional view of the multi-flex board 100 corresponding to section A-A′ is depicted in FIG. 1B. In FIG. 1B, the layers 102, 104, 106 and 108 are shown as Layer 1, Layer 2, Layer 3 and Layer 4, respectively. The four-layer architecture provides even thickness to the entire multi-flex board 100. A minimum thickness chosen for the fabrication of such a multi-flex board is 20 mils (+/−3 mils with 15 mil antenna feed trace impedance matching), where a ‘mil’ is a unit of length, which corresponds to a thousandth of an inch. It is noted that a number of layers in the multi-flex board 100 is optimized to four in accordance with the requirements of ultra-thin thickness profile for high flexibility and less manufacturing cost, as desired by consumer electronics. It is understood that the multi-flex board 100 is configured to include one or more component assembly areas on which electronic components such as integrated circuits and passive components may be assembled. A simplified representation of the multi-flex board 100 including multiple component assembly areas is shown in FIG. 2.

FIG. 2 shows a simplified representation of the multi-flex board 100 of FIG. 1B including multiple component assembly areas, in accordance with an example scenario. In an example scenario, components (such as electronic components like integrated circuits, passive components etc. may be assembled on a top portion of the multi-flex board 100 in component assembly areas 202, 204, 206 and 208 as shown in FIG. 2. Additionally, to ensure feasibility of assembly, one or more stiffeners, such as stiffeners 210, 212, 214 and 216, may be included at a bottom portion of the multi-flex board 100, as shown in FIG. 2. It is noted that the stiffeners 210-216 increase a thickness of the multi-flex board 100, which makes the multi-flex board 100 difficult to bend or twist. A stack-up view of the four-layer architecture of the multi-flex board 100 is shown in FIG. 3.

FIG. 3 shows a stack-up view of the multi-flex board 100 of FIG. 1B in accordance with an example scenario. As explained with reference to FIGS. 1A and 1B, the multi-flex board 100 includes four layers 102, 104, 106 and 108 (or Layer 1, Layer 2, Layer 3 and Layer 4, respectively). The layers 1, 2, 3 and 4 of the multi-flex board 100 are made of a conductive material, such as copper.

The first flex copper clad laminate (FCCL) layer 306 consists of Layer 1, Layer 2, two adhesive layers 306a and 306b and a polyimide layer 306c. The second FCCL layer 308 consists of Layer 3, Layer 4, two adhesive layers 308a and 308b and a polyimide layer 308c. Since each FCCL layer includes two copper layers, it is called double-sided copper-clad laminate. It is a complex film where two adhesive layers are coated on one polyimide layer and two copper foils are coated on top of each adhesive layer.

Further, coverlays, such as a top coverlay 302 and a bottom coverlay 304 are provided on the top and bottom portion of the multi-flex board 100, respectively. The coverlays 302 and 304 are used to protect the circuits and systems on the multi-flex board 100 from environmental and electrical interference. A coverlay usually includes a polyimide layer and an adhesive layer. Accordingly, the top coverlay 302 includes a polyimide layer 302a and an adhesive layer 302b, whereas the bottom coverlay 304 includes a polyimide layer 304a and an adhesive layer 304b. It is noted that a polyimide layer such as the polyimide layers 302a or 304a includes polyimide, which is a widely-used laminate material used in flex PCBs.

It is understood that a laminate is a substrate material for PCBs and it is the base film for the conductor. Polyimide is typically chosen as the laminate material because it combines chemical stability, temperature tolerance and mechanical strength with good dielectric properties. An adhesive is the material that can glue a laminate with a conductor or a laminate with another laminate. An adhesive layer, such as the adhesive layer 302b or 304b includes acrylic or epoxy, which are the most common chemical materials used for adhesives.

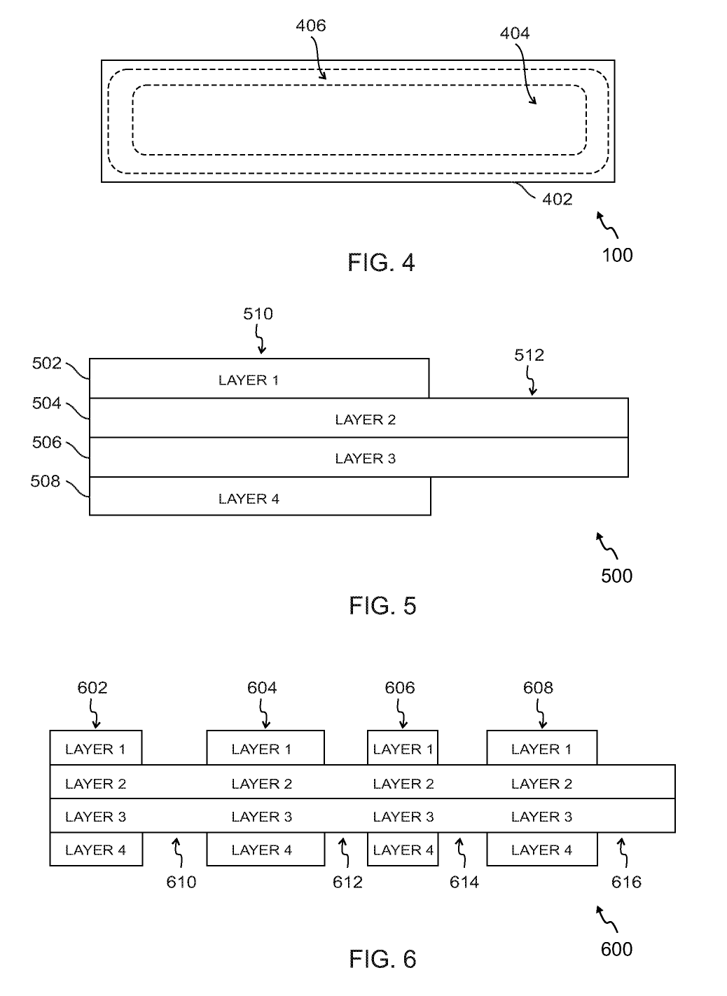

Furthermore, a bond ply layer 310 is included between the Layers 2 and 3. The bond ply layer 310 includes two adhesive layers 310a and 310b and a polyimide layer 310c. A simplified top-view representation of the multi-flex board 100 is depicted in FIG. 4.

FIG. 4 shows a simplified top-view representation of the multi-flex board 100 for illustrating power and ground planes, in accordance with an example scenario. The top-view representation shows a board outline 402 of the multi-flex board 100 with a solid ground plane 404 and a power plane 406 which are made of copper. The outlines of the solid ground plane 404 and the power plane 406 are shown by dotted lines in FIG. 4 as typically these planes would be disposed in one of the layers of the multi-flex board 100 and not the top coverlay, such as the layer 102, 104, 106 and 108 as depicted in FIG. 3. It is noted that solid power planes and ground planes are usually preferred for four-layer board design, since this method provides clean power supply, reduces noise coupling issues and cross-talk scenarios.

The conventional design of the multi-flex board 100 as described with reference to figures from FIGS. 1A to 4 has several drawbacks. For example, even though the multi-flex board 100 is relatively thin (around 20-mil thickness) it cannot bend in a very flexible way. Moreover, if this design is flexed many times, solder pads (used for soldering one or more components on the multi-flex board 100) experience too much force, which could cause the components to fall off the board. This is because of the fact that 20-mil thickness along a cycle is still too thick to meet the bendability requirement. Moreover, as depicted in FIG. 4, the power planes and ground planes traverse the entire span of the multi-flex board 100 and therefore those big areas of copper enhance the rigidity and heavily impact the bend radius. Further, a chance that the copper could stretch and crack on account of the bending also increases. Consequently, a PCB design for a multi-flex board as explained in FIGS. 1A-4 is not reliable and is not capable of bending flexibly.

Various embodiments of the present technology provide a multi-flex printed circuit board system that is capable of overcoming these and other obstacles and providing additional benefits. More specifically, various embodiments of the present technology disclosed herein present a PCB design for a multi-flex printed circuit board structure that is capable of meeting requirements such as ultra-thin thickness profile of the board (thereby allowing 360 degree of bendability) and less manufacturing cost, as desired by consumer electronics, such as wearable motion controlled mobile gaming devices. Moreover, the proposed design also conforms to reliability requirement including trusty thermal stress test, solder-mask adhesive test and solderability test. A PCB design for such a multi-flex printed circuit board system is explained with reference to FIGS. 5 to 12.

FIG. 5 shows an example PCB design of a multi-flex printed circuit board 500, in accordance with an embodiment of the present invention. The multi-flex printed circuit board 500 is hereinafter referred to as the multi-flex board 500. The PCB design of the multi-flex board 500 depicts four layers, 502, 504, 506 and 508, referred to hereinafter as Layer 1, Layer 2, Layer 3 and Layer 4. The Layers 1 to 4 form a section 510 of four-layer thickness. Layers 2 and 3 extend out from the section 510 to form a section 512 of two-layer thickness. In an example scenario, the section 510 including all the Layers 1-4 has a thickness of around 20 mils whereas the section 512 including the Layers 2 and 3 has a thickness of around 7-8 mils thickness. Further, the ground and supply planes are configured to be disposed only on the section 510, i.e. the thicker section with a four-layer thickness, whereas the signal paths are provisioned on the section 512, i.e. a thinner section with a two-layer thickness. As a result of such a configuration, the multi-flex board 500 is completely bendable along its entire rectangular surface and can be bent as a cycle. Such a design of the PCB including a combination of four layers and two layers is hereinafter referred to as ‘4-2 layers combination’.

FIG. 6 shows a perspective side view of a multi-flex board structure 600 including multiple 4-2 layers' combinations, in accordance with an example embodiment of the present invention. More specifically, the multi-flex board structure 600 includes multiple sections of four-layer thickness, such as for example, section 602, 604, 606 and 608, and multiple sections of two-layer thickness, such as sections 610, 612, 614 and 616. Moreover, consecutive sections of four-layer thickness are connected by a section with a two-layer thickness. For example, the sections 602 and 604 of four-layer thickness are connected by the section 610 of two-layer thickness and so on and so forth. It is noted that all sections of four-layer thickness, i.e. the sections 602, 604, 606 and 608 are around 20 mils in thickness each, and the sections of two-layer thickness, such as sections 610, 612, 614 and 616 are around 7-8 mils in thickness each. The ultra-thin sections 610, 612, 614 and 616 dramatically increase the flexibility of the multi-flex board structure 600 and ensure that a multi-flex PCB system (i.e. a multi-flex board with electronic components soldering on) can be bent as a circle.

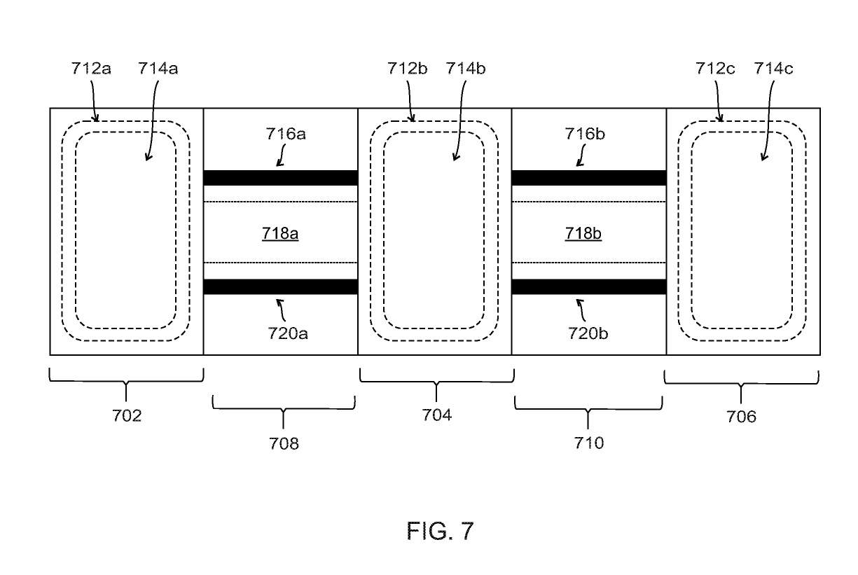

Furthermore, the components are to be soldered on top of Layer 1 and/or Layer 4 of sections with four-layer thickness depending on the complexity of the design to be implemented on the multi-flex board structure 600. All the sections with two-layer thickness are used for routing and bending. The routing includes power, ground traces and all the necessary signal paths as explained with reference to FIG. 7.

FIG. 7 shows a simplified representation of a top view of a portion of the multi-flex board structure 600 of FIG. 6 for illustrating ground planes, ground traces, power planes, power traces and signal path zone placements, in accordance with an example embodiment of the present invention. In an embodiment, the portion of the multi-flex board structure 600 is depicted to show three sections of four-layer thickness, such as a section 702, a section 704 and a section 706, and two sections of two-layer thickness, such as a section 708 and a section 710.

In an embodiment, the sections 702, 704 and 706 are configured to include a power plane and a ground plane. For example, the section 702 includes a power plane 712a and a ground plane 714a; the section 704 includes a power plane 712b and a ground plane 714b; and the section 706 includes a power plane 712c and a ground plane 714c. The power plane is not necessarily larger than the ground plane or vice versa. However, for EMI consideration, the power plane or the ground plane is normally designed to enclosed by the other one.

Further, the power traces, signal path zones and ground traces are disposed on the sections with two-layer thickness. For example, the section 708 is configured to include a power trace 716a, a signal path zone 718a and a ground trace 720a. Similarly, the section 710 is configured to include a power trace 716b, a signal path zone 718b and a ground trace 720b as shown in FIG. 7. It is noted that one of the major differences of such a configuration over a configuration explained with reference to FIGS. 1A to 4 and more specifically depicted in FIG. 4 is that the ground and power planes (such as the ground plane 404 and the power plane 406 depicted in FIG. 4) are both solid and cover the entire board, whereas as in FIG. 7, the power planes 712a, 712b and 712c and the ground planes 714a, 714b and 714c are piecewise continuous and only solid within the sections 702, 704 and 706 with four layer thickness. The piecewise continuous power and ground planes significantly reduces the amount of copper on sections of two-layer thickness and makes the multi-flex board much easier to bend. In the meantime, the piecewise continuous design also maximizes the power and ground planes to maintain a fairly good noise performance.

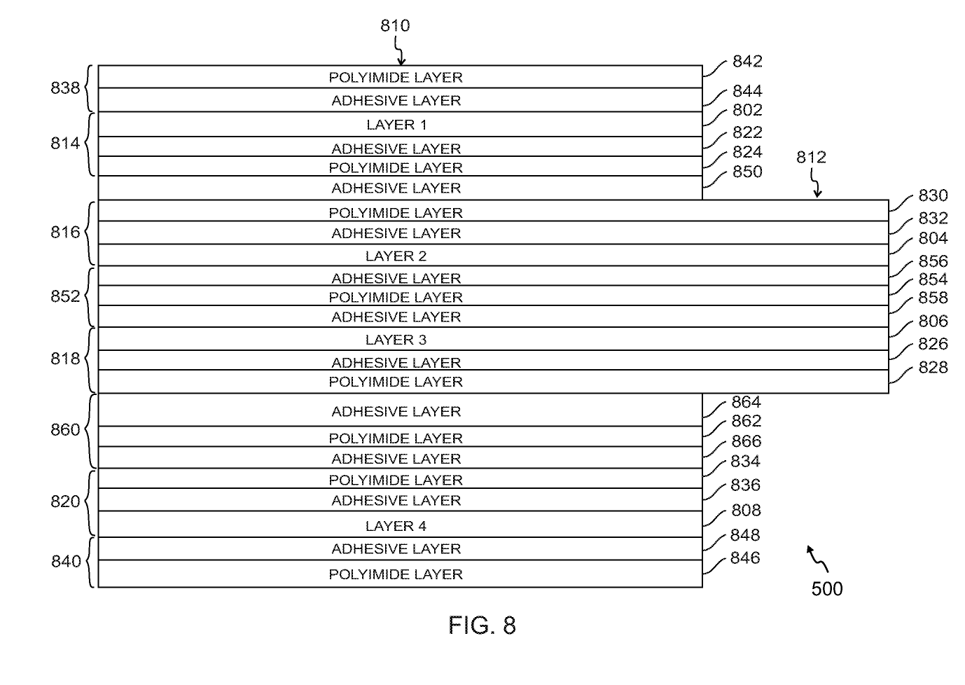

The relatively wide power traces, such as the power traces 716a and 716b are used to connect the power planes 712a, 712b and 712c, whereas the ground traces, such as the ground traces 720a and 720b are used to connect the ground planes 714a, 714b and 714c, in between two successive sections of four-layer thickness. It is noted that signals in the multi-flex board system can be routed in the signal path zones, such as the signal path zones 718a and 718b. A stack up view of a multi-flex board is shown in FIG. 8.

FIG. 8 shows a stack-up view of the multi-flex board 500 of FIG. 5, in accordance with an example embodiment of the present invention. As explained with reference to FIG. 5, the multi-flex board 500 includes a ‘4-2 layer’ combination, or more specifically, four layers are arranged in a manner such that a section is formed with four-layer thickness and another section is formed with two-layer thickness.

Accordingly, the stack-up view of the multi-flex board 500 depicts four layers: Layer 1, Layer 2, Layer 3 and Layer 4 (also labeled as layers 802, 804, 806 and 808, respectively). The Layers 1, 2, 3 and 4 of the multi-flex board 500 are made of a conductive material, such as copper. The Layers 1, 2, 3 and 4 are arranged in a manner to form a section 810 of four-layer thickness (i.e. including four copper layers among other layers) and another section 812 of two-layer thickness (including two copper layers among other layers). The Layers 1, 2, 3, 4 are included within four FCCLs, such as FCCL 1, FCCL 2, FCCL 3 and FCCL 4 labeled as layers 814, 816, 818 and 820. FCCLs 1 and 3 are double-sided copper clad laminate with bottom copper foil etched off. Thus, a copper layer (i.e. Layer 1), an adhesive layer 822 and a polyimide layer 824 form the FCCL 1 (i.e. layer 814) and a copper layer (i.e. Layer 3), an adhesive layer 826 and a polyimide layer 828 form the FCCL 3 (i.e. layer 818). Furthermore, FCCLs 2 and 4 are double-sided copper clad laminate with top copper foil etched off. Therefore, FCCL 2 (i.e. layer 816) includes a polyimide layer 830, an adhesive layer 832 and a copper layer (i.e. Layer 2) and FCCL 4 (i.e. layer 820) consists of a polyimide layer 834, an adhesive layer 836 and a copper layer (i.e. Layer 4).

Further, coverlays, such as a top coverlay 838 and a bottom coverlay 840 are provided on the top and bottom portion of the multi-flex board 500, respectively. The coverlays 838 and 840 are used to protect the circuits and systems on the multi-flex board 500. A coverlay usually includes a polyimide layer and an adhesive layer. The top coverlay 838 includes a polyimide layer 842 and an adhesive layer 844, whereas the bottom coverlay 840 includes a polyimide layer 846 and an adhesive layer 848 as shown in FIG. 8.

Further, the multi-flex board 500 includes an adhesive layer 850 disposed between the FCCLs 1 and 2 (i.e. layers 814 and 816). Two bond ply layers are included between FCCLs 2 and 3 (i.e. layers 816 and 818) and FCCLs 3 and 4 (i.e. layers 818 and 820), respectively. The first bond ply layer 852 is formed by a polyimide layer 854 and two adhesive layers 856 and 858 coated on it. The second bond ply layer 860 is also composed of one polyimide layer 862 and two adhesive layers 864 and 866 in the same form.

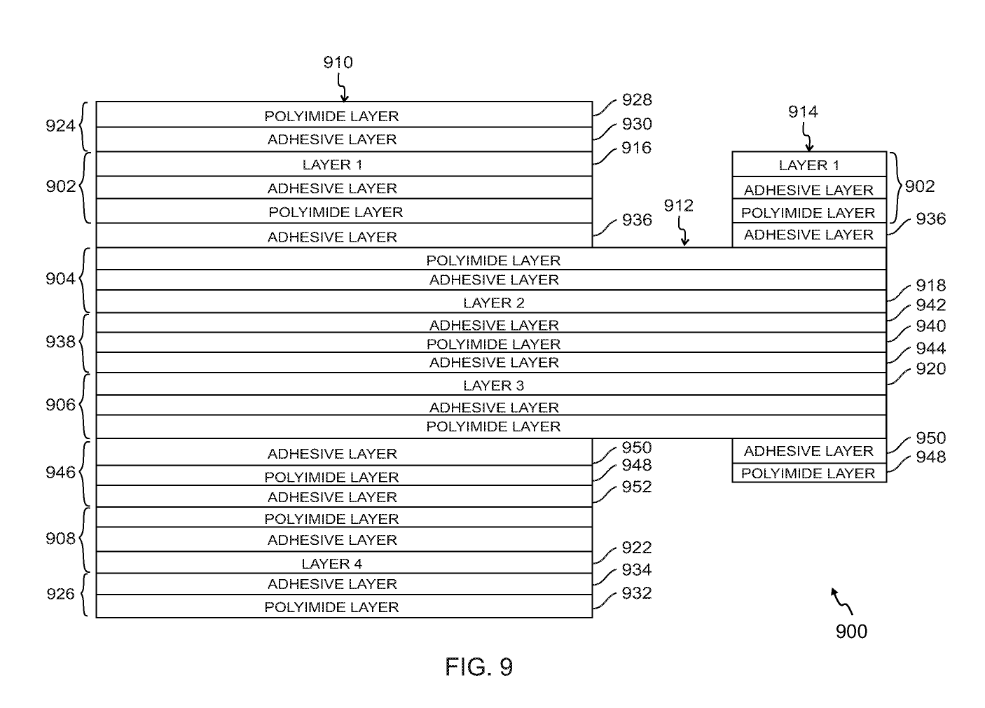

The FCCLs 2 and 3 (i.e. layers 816 and 818) extend out of the section 810 and form the section 812, which has a thickness of around a 7-8 mils to give a reasonable impedance control capability to the multi-flex board 500. The multi-flex board structure as depicted in FIG. 8 may be directly modified to a ‘4-3-2 layers’ combination. Such a layer combination may be used if the electronic system to be accommodated on the PCB structure is fairly complicated. A stack-up view of a PCB design of ‘4-3-2 layers’ combination for a multi-flex board is depicted in FIG. 9.

FIG. 9 shows a stack up view of a PCB design of ‘4-3-2 layers’ combination for a multi-flex board 900, in accordance with an embodiment of the present invention. The stack-up view of the multi-flex board 900 depicts four FCCLs: FCCL 1, FCCL 2, FCCL 3 and FCCL 4 (shown in FIG. 9 as layers 902, 904, 906 and 908, respectively) arranged in a manner to form a section 910 of four-layer thickness, a section 912 of two-layer thickness and another section 914 of three-layer thickness.

The Layers 1, 2, 3 and 4 (also shown as 916, 918, 920 and 922) of the multi-flex board 900 are made of a conductive material, such as copper. The Layers 1, 2, 3, 4 are included within four FCCLs, such as FCCL 1, FCCL 2, FCCL 3 and FCCL 4.

The section 910 includes a top coverlay 924 disposed of a top portion of the FCCL 1 and a bottom coverlay 926 disposed on a bottom portion of the FCCL 4. The top coverlay 924 includes a polyimide layer 928 and an adhesive layer 930 and the bottom coverlay 926 includes a polyimide layer 932 and an adhesive layer 934 as shown in FIG. 9. Furthermore, the multi-flex board 900 includes an adhesive layer 936 between the FCCL 1 and 2 (i.e. the layers 902 and 904). A bond ply layer 938 is included between FCCLs 2 and 3 (i.e. the layers 904 and 906) and the bond ply layer 938 includes a polyimide layer 940 which is disposed in-between two adhesive layers 942 and 944. Furthermore, a bond ply layer 946 included between FCCLs 3 and 4 (i.e. layers 906 and 908) has a polyimide layer 948 which is disposed in between two adhesive layers 950 and 952 as shown in FIG. 9.

The middle FCCLs 2 and 3 extend out of the section 910 and form the section 912, which has a thickness of around a 7-8 mils to give a reasonable impedance control capability to the multi-flex board 900. In an embodiment, the section 914 has a thickness of around 12 to 13 mils (i.e. around 0.3 mm). The section 914 is shown to include an extended portion of the section 912 and portions of the FCCL 1 (i.e. layer 902), the adhesive layer 936, adhesive layer 950 and polyimide layer 948 as shown in FIG. 9.

In an embodiment, the multi-flex board 900 accommodates complex designs with additional routing space when compared with the multi-flex board 500 of FIG. 8 due to the additional section 914. In an embodiment, 0.3 mm thickness of the section 914 is a standard requirement of a 0.5 pitch flat printed circuit (FPC) connector. Accordingly, such a PCB design of the multi-flex board 900 is adaptive to complex designs and flexible to be used for a design either requiring FPC connectors or not. The conventional PCB design as explained with reference to figures from FIGS. 1A to 4 does not include such a capability.

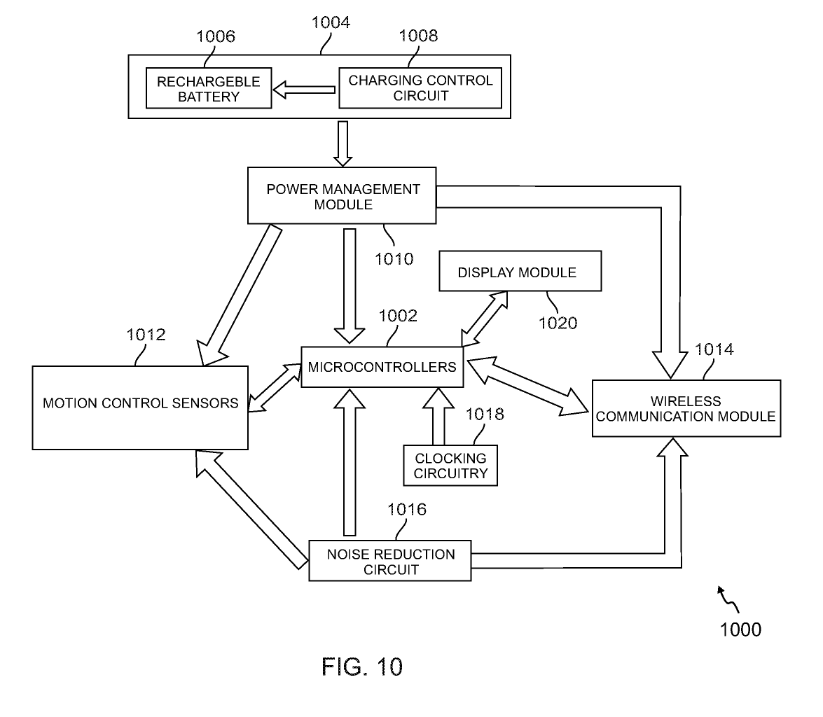

FIG. 10 shows an example electronic system 1000 for use in a motion controlled gaming device, in accordance with an embodiment of the invention. The electronic system 1000 is hereinafter referred to as system 1000.

As depicted in FIG. 10, the system 1000 includes a processing circuitry in the form of one or more microcontrollers 1002, a battery module 1004 including a rechargeable battery 1006 and a charging control circuit 1008, a power management module 1010, one or more motion control sensors 1012 (such as for example, initial measurement unit (IMU) sensors, such as gyroscope, magnetometer, accelerometer etc.), a wireless communication module 1014 (including wireless transceivers to communicate for example with smartphone, tablet, smart TV, VR headset application ecosystem or with cloud-based applications), a noise reduction circuit 1016 and clocking circuitry 1018. Further, the system 1000 may include a display module 1020 including buttons and light emitting diodes (LEDs) for implementing external interrupts. It is noted that, the components 1002-1020 are depicted in FIG. 10 are for example purposes only, and that the system 1000 may include more or fewer number of components than those depicted in FIG. 10.

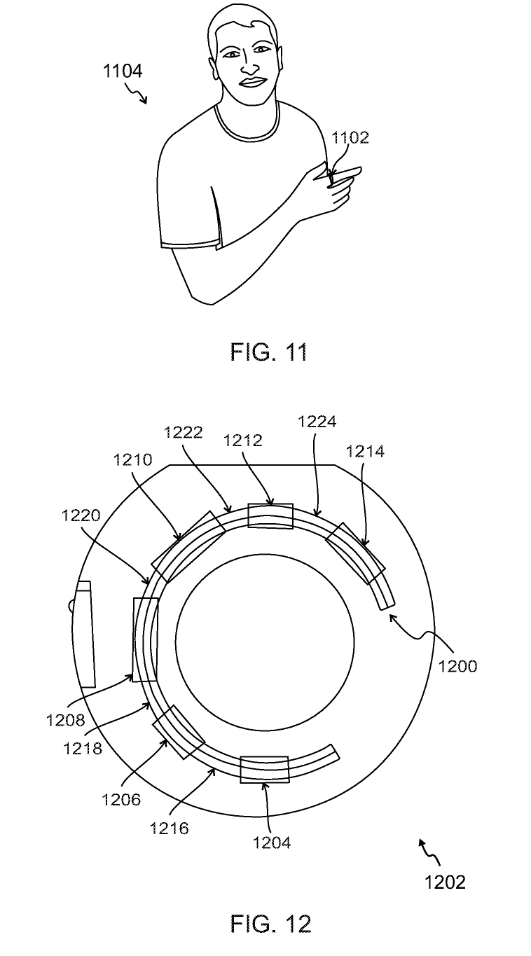

In an example embodiment, the system 1000 may be implemented on one or more multi-flex boards such as the multi-flex board 500 or the multi-flex board 900 explained above, so as to configure a multi-flex printed circuit board system. The multi-flex PCB system may be assembled for use within a consumer electronic device, such as a wearable motion controlled gaming device. One such implementation is explained with reference to FIGS. 11 and 12.

FIG. 11 shows an example representation of a motion controlled gaming device 1102 implemented as a ring of a user 1104, in accordance with an example scenario. As explained with reference to FIG. 10, a multi-flex PCB system may be configured by implementing multi-flex boards in a ‘4-2 layers’ combination or a ‘4-3-2 layers’ combination, which allow almost 360-degree bendability of the multi-flex boards. Moreover, both of ‘4-2 layers’ combination and the ‘4-3-2 layers’ combination shift all the component assembly load to relatively thicker layer sections and only enable the routing capability to the thinner layer sections. As a result, the thinner layers can be used for bending and the components are less likely to fall off on account of bending. Moreover, the choice of material as well as architecture enables the multi-flex PCB system to be manufactured within an affordable range for a retail product. As a result, the multi-flex PCB system may be used in consumer electronic devices with high flexibility and low cost requirements, such as, for example, wearable motion controlled gaming devices. An outer shell of one such wearable motion controlled gaming device configured in shape of a ring is depicted in FIG. 11. An example deployment of the multi-flex board assembly within the outer shell of the ring is depicted in FIG. 12.

FIG. 12 depicts an example representation of a multi-flex PCB system 1200 disposed within an outer shell of a circular-shaped wearable motion controlled gaming device 1202, in accordance with an embodiment of the invention. As can be seen, the multi-flex PCB system 1200 is implemented as a ‘4-2 layers’ combination multi-flex PCB composed of six four-layer thickness sections 1204, 1206,1208,1210,1212 and 1214 interconnected by five two-layer thickness sections 1216,1218,1220, 1222 and 1224. In an embodiment, the circular-shaped wearable motion controlled gaming device 1202 may correspond to any one of a band, a bracelet, a circular-pendant, circular-charms, a ring, a circular-earring, circular-brooches and the like. It is noted that six four-layer thickness sections 1204-1214 and five two-layer thickness sections 1216-1224 configuring the multi-flex PCB system 1200 are shown for example purposes only, and that the multi-flex PCB system 1200 may include more or fewer number of sections than those depicted in FIG. 12. Moreover, the number of four-layer and two-layer thickness sections configuring the multi-flex PCB system 1200 may also depend on a complexity level of an electronic system, such as the system 1000 explained with reference to FIG. 10.

As depicted in FIGS. 5 to 9, the proposed PCB is rectangular in shape and the design is focused on maximizing utilization of the entire internal circumference of the round shape wearable motion controlled mobile gaming device. Therefore, in at least some embodiments, a width of the multi-flex PCB system 1200 is determined by the size of the largest IC (Integrated Circuit) chip and the space requirement from the components to the board boundary. Such a distance may be determined by the capability of a fabrication house. Moreover, a length of the multi-flex PCB system 1200 may also be determined by several aspects such as system functionality and complexity, and also a layout and the component placement to be accommodated thereon. In some cases, the length of the multi-flex PCB system 1200 may not be perfectly equal to the internal perimeter of the round or band shaped wearable device. In at least some embodiments, a length of the multi-flex PCB system 1200 may be shorter as exemplarily depicted in FIG. 12. If the length of the multi-flex PCB system 1200 is longer than the perimeter of the wearable device, the multi-flex PCB system 1200 could be wrapped around. In such a case, the possible interference between IC chips and the possible shorted circuits may have to be carefully taken care of.

It is noted that since the proposed solution is an ultra-thin design, extreme heat during assembly can curve the multi-flex boards. One of the traditional ways is to use stiffeners to add hardness to the multi-flex boards. As demonstrated in FIG. 2, the stiffeners 210, 212, 214, 216 are added on the bottom of the multi-flex board 100. They are located at certain sections where the components are assembled to ensure that the practical assembly can be carried out successfully. However, stiffeners increase the thickness of a multi-flex board and as a result, the PCB is even harder to bend. Furthermore, only single side soldering is permitted in order to having stiffeners on the other side. Thus, this is not a desirable solution for complicated systems, which require double-side soldering. Instead of using stiffeners, in at least some embodiments, panelization may be used to fix the multi-flex board during the assembly. As the shape of a multi-flex board is rectangular, therefore, it is easy to make a panel. Another benefit of panelization is that double-side soldering can be achieved if it is needed.

Moreover, for reasonable cost and high reliability performance either under high temperature soldering processes or variant daily circumstances, DuPont Pyralux FR may be used for flexible composites such as adhesive layers and coverlay layers as described in FIGS. 5-9. Also, it is noted that a solder floating resistance for soldering components in the multi-flex board assembly is 10-second at 288 centigrade degree.

Various example embodiments offer, among other benefits, techniques for a multi-flex PCB design for use in consumer electronic devices, such as wearable motion controlled mobile gaming devices. The proposed multi-flex PCB design is ultra-thin and 360 degree bendable. The board architecture and the selection of the materials make the PCB to achieve the requirement for different sizes and shapes (such as ring, band, bracelet, etc.) of the wearable devices for motion controlled mobile gaming. For some shapes, which only require a flat surface, the standard rigid PCB may also be chosen. Further, a manufacturing cost for the board is also controlled in a safe range, which keeps the wearable device at an affordable retail price. Also, the multi-flex board maintains good noise performance and routing capability. Furthermore, the multi-flex board structure could be easily transformed from a 4-2 layers' combination to a 4-3-2 layers' combination and take on flexibility of single side soldering and double side soldering. Hence, it is considered as a highly adaptive design to either relatively simple system or complex system for mobile gaming devices. Moreover, the 4-2 layers' combination or the 4-3-2 layers' combination of the multi-flex board design may be implemented for any wearable devices that are having quasi-band shape such as a bracelet, a ring, a circular earring and circular brooches etc.

The foregoing descriptions of specific embodiments of the present invention have been presented for purposes of illustration and description. They are not intended to be exhaustive or to limit the present invention to the precise forms disclosed, and obviously, many modifications and variations are possible in light of the above teaching. The exemplary embodiment was chosen and described in order to best explain the principles of the present invention and its practical application, to thereby enable others skilled in the art to best utilize the present invention and various embodiments with various modifications as are suited to the particular use contemplated.

Accordingly, the disclosure of the present invention is intended to be illustrative, but not limiting, of the scope of the invention, which is set forth in the following claims.

1. A printed circuit board design for a multi-flex board, the multi-flex board comprising:
a plurality of sections made up of flexible composites and a conductive material that allows complete bendability of the multi-flex board, wherein each section is configured with a desired combination of layers;
one or more components soldered on top and/or bottom copper layer;
wherein the multi-flex board is configured to enable component assembly load on one or more thicker layer sections and routing capability to one or more thinner layer sections; and
wherein middle layers of the thicker layer section extend out to form the thinner layer section.

2. The multi-flex board of claim 1 is the optimal types of PCB's in consumer electronic devices with high flexibility and complete bendability requirement.

3. The multi-flex board of claim 1 wherein the thinner layer sections are used for bending thereby eliminating bending of components configured on the thicker layer section.

4. The multi-flex board of claim 1 wherein the material and design of the multi-flex board enables the multi-flex board to be manufactured with low cost and high flexibility thereby allowing the multi-flex board to be used in desired consumer wearable devices.

5. The multi-flex board of claim 1 wherein the multi-flex board is configured as one of a four-two layers' combination and a four-three-two layers' combination.

6. The multi-flex board of claim 5 wherein the four-two layers' combination multi-flex board in configured with a first thick section formed with four-layer thickness and a second thin section formed with a two-layer thickness.

7. The multi-flex board of claim 5 wherein the four-three-two layers' combination multi-flex board in configured three sections including a four-layer thickness, a two-layer thickness and three-layer thickness.

8. The multi-flex board of claim 5 wherein the multi-flex board structure is transformed from a four-two layers' combination to a four-three-two layers' combination thereby achieving high adaptive design.

9. The multi-flex board of claim 1 wherein the thicker layer and the thinner layer are connected together.

10. The multi-flex board of claim 6 wherein the section of two-layer thickness is an ultra-thin section that increases the flexibility of the multi-flex board structure to ensure that the multi-flex board is bent completely along its rectangular surface as a circle.

11. The multi-flex board of claim 1 wherein the thicker layer is designed with a power plane and a ground plane.

12. The multi-flex board of claim 1 wherein the thinner layer is used for routing and bending.

13. The multi-flex board of claim 1 and 6 wherein the power and ground planes are piecewise continuous thereby reducing the amount of copper on sections of two-layer thickness to make the multi-flex board easier to bend, wherein the piecewise continuous design maximizes the power and ground planes to maintain a good noise performance.

14. The multi-flex board of claim 12 wherein the routing further comprises power traces, ground traces and all necessary signal paths.

15. The multi-flex board of claim 6 and claims 11 to 14 wherein the power and ground traces are used to connect power and ground planes in between two successive sections of four-layer thickness.

16. The multi-flex board of claim 1 and further comprising:
a top coverlay and a bottom coverlay provided at the top portion and bottom portion of the multi-flex board respectively, wherein each coverlay is made up of a polyimide layer and an adhesive layer.

17. The multi-flex board of claim 16 wherein the coverlays are used to protect the circuits and system on the multi-flex board.

18. The multi-flex board of claim 1 wherein the thicker layer section has a maximum of four copper layers to optimize the balance between the price and the quality.

19. The multi-flex board of claim 18 wherein a minimum thickness is chosen for the four-copper layer section of a multi-flex board.

20. The multi-flex board of claim 5 wherein the four-two layers' combination further comprises:
four FCCL wherein, a first and third FCCL are double-sided copper clad laminate with bottom copper foil etched off, and a second and fourth FCCL are double-sided copper clad laminate with top copper foil etched off;
an adhesive layer disposed between the first FCCL and the second FCCL; and
two bond ply layers configured between the second FCCL to a third FCCL and between the third FCCL to a fourth FCCL respectively.

21. The multi-flex board of claim 18 wherein each of the bond ply layers are formed by a polyimide layer and two adhesive layers are coated on it.

22. The multi-flex board of claim 1 wherein the printed circuit board is rectangular in shape and length is determined based on consumer wearable device thereby achieving requirement for various sizes and shapes and width is determined by the size of the largest Integrated Circuit chip and the space requirement from the components to the printed circuit board boundary.

23. The multi-flex board of claim 1 and further comprising:
a panel of a plurality of multi-flex boards assembled together thereby fixing the multi-flex boards to have capability and reliability of double-side soldering.
